(19) United States
(12) Patent Application Publication
(10) Pub. No.: US 2013/0026648 A1
(43) Pub. Date: Jan. 31, 2013

(54) FILM FOR FORMING SEMICONDUCTOR PROTECTION FILM, AND SEMICONDUCTOR DEVICE

(71) Applicants: Takashi Hirano, Shinagawa-ku (JP); Masato Yoshida, Shinagawa-ku (JP)

(72) Inventors: Takashi Hirano, Shinagawa-ku (JP); Masato Yoshida, Shinagawa-ku (JP)

(21) Appl. No.: 13/520,423

(22) PCT Filed: Aug. 5, 2010
(86) PCT No.: PCT/JP10/04932

§ 371 Date: Jul. 3, 2012

(30) Foreign Application Priority Data
Jan. 20, 2010 (JP) 2010-010228
Feb. 10, 2010 (JP) PCT/JP10/00810

(51) Int. Cl. C08L 63/00; C08K 3/22; H01L 23/48

(52) U.S. Cl. 257/774; 523/400; 523/457; 257/E23.011

(57) ABSTRACT

Disclosed is a film for forming a semiconductor protection film, which protects a surface of a semiconductor element that is mounted on a structure such as a substrate and is located on the outermost side, the surface being on the reverse side of the surface at which the semiconductor element is mounted on the structure, and the resin composition constituting the film for forming a semiconductor protection film contains (A) a thermosetting component and (B) an inorganic filler.

### TECHNICAL FIELD

The present invention relates to a film for forming a semiconductor protection film having excellent protective properties for semiconductor elements, and a semiconductor device using the film.

### BACKGROUND ART

In recent years, miniaturization and weight reduction of semiconductor devices have been promoted, and packages such as a Ball Grid Array (μBGA) and a Chip Size Package (CSP) have been developed. However, in the packages such as the μBGA and the CSP, a semiconductor element has a face-down structure, that is, a structure in which the circuit surface of a semiconductor element is disposed toward the semiconductor substrate side. Therefore, the semiconductor element has a structure that the back surface of the semiconductor element is exposed at the top of the package, and when a package is produced or when a package is conveyed, there are problems that terminals of the semiconductor element break off and the like. As a solution for these problems, methods of bonding a protective film to the back surface of a semiconductor element have been disclosed (see, for example, Patent Documents 1 to 3).

### RELATED DOCUMENTS

### Patent Documents

PATENT DOCUMENT 1: Japanese Patent Application Laid-Open No. 2002-280329
PATENT DOCUMENT 2: Japanese Patent Application Laid-Open No. 2007-250970
PATENT DOCUMENT 3: Japanese Patent Application Laid-Open No. 2006-140348

### SUMMARY OF THE INVENTION

However, in these methods, since binder polymer components are used in the protective film, when a semiconductor element is mounted on a substrate using a flip chip bonder or the like, there is a problem that the marks of collets are imprinted, or the scratch prevention function is not sufficiently exhibited. Furthermore, as the thickness reduction of semiconductor elements and semiconductor substrates is underway, warpage of packages has become a problem.

An object of the present invention is to provide a film for forming a semiconductor protection film having excellent protective properties for semiconductor elements, and a semiconductor device with less warpage, which has a semiconductor protection film formed by using the film for forming a semiconductor protection film.

According to the present invention, there is provided a film for forming a semiconductor protection film, which protects a surface of a semiconductor element that is mounted on a base material and is located on the outermost side, the surface being on the reverse side of the surface at which the semiconductor element is mounted on the base material, wherein a resin composition that constitutes the film for forming a semiconductor protection film contains (A) a thermosetting component and (B) an inorganic filler.

Furthermore, according to the present invention, there is provided a semiconductor device in which a surface of a semiconductor element that is mounted on a base material and is located on the outermost side, the surface being on the reverse side of the surface at which the semiconductor element is mounted on the base material, is protected by a semiconductor protection film, wherein the semiconductor protection film is formed from a cured product of the film for forming a semiconductor protection film described above.

According to the present invention, a film for forming a semiconductor protection film having excellent protective properties for semiconductor elements, and a semiconductor device with less warpage, which has a semiconductor protection film formed by using the film for forming a semiconductor protective film, can be obtained.

### BRIEF DESCRIPTION OF THE DRAWING

The objects described above, other purposes, features and advantages will be further revealed by a suitable embodiment that will be described below, and by the following drawing associated with the embodiment.

FIG. 1 is a flow diagram illustrating an example of the method for producing a semiconductor device of the present invention.

### DESCRIPTION OF EMBODIMENTS

The film for forming a semiconductor protection film of the present invention is a film for forming a semiconductor protection film, which protects a surface of a semiconductor element that is mounted on a base material and is located on the outermost side, the surface being on the reverse side of the surface at which the semiconductor element is mounted on the base material, and the resin composition that constitutes the film for forming a semiconductor protection film contains (A) a thermosetting component and (B) an inorganic filler, so that the film for forming a semiconductor protection film can thereby protect the semiconductor element from the generation of cracks. Furthermore, the semiconductor device of the present invention is a semiconductor device in which a surface of a semiconductor element that is mounted on a base material and is located on the outermost side, the surface being on the reverse side of the surface at which the semiconductor element is mounted on the base material, is protected by a semiconductor protection film, wherein the semiconductor protection film is formed from a cured product of the film for forming a semiconductor protection film described above. Thereby, the collet marks or scratches occurring when a semiconductor element is mounted on a substrate using a flip chip bonder or the like, can be prevented. Also, a semiconductor device with less warpage can be obtained. According to the present invention, examples of the base material include a resin substrate, and a structure in which plural semiconductor elements are laminated on a resin substrate. Hereinafter, a film for forming a semiconductor protection film of the present invention, a semiconductor device of the present invention, and a method for producing the semiconductor device will be described in detail.

The lower limit of the weight average molecular weight of the resin component in a resin composition which constitutes a protection film-forming layer (hereinafter, also referred to as “film resin composition”) is preferably 100 or greater, and more preferably 200 or greater. The upper limit of the weight average molecular weight of the resin component in the film resin composition is preferably 49,000 or less, and more preferably 40,000 or less. When the weight average molecular weight of the resin component is in the range described above, a protection film-forming layer which has a high glass transition temperature after curing, while maintaining film-forming properties, can be obtained.

In a resin composition which constitutes the film for forming a semiconductor protection film of the present invention (hereinafter, also referred to as “film resin composition”), (A) a thermosetting component is used. The (A) thermosetting component is not particularly limited as long as it is a resin which undergoes a thermosetting reaction by itself, or a resin which undergoes a thermosetting reaction when used together with a curing agent, but examples thereof include epoxy resins such as bisphenol type epoxy resins including a bisphenol A epoxy resin, and a bisphenol F epoxy resin; novolac type epoxy resins including a novolac epoxy resin, and a cresol novolac epoxy resin; biphenyl type epoxy resins, stilbene type epoxy resins, triphenolmethane type epoxy resins, alkyl-modified triphenolmethane type epoxy resins, triazine nucleus-containing epoxy resins, dicyclopentadiene-modified phenol type epoxy resins, and diglycidylamine type epoxy resins; resins having a triazine ring such as urea resins and melamine resins; unsaturated polyester resins; bismaleimide resins; polyurethane resins; diallyl phthalate resins; silicone resins; resins having a benzoxazine ring; cyanate ester resins, and modified phenoxy resins. These may be used singly or as mixtures. Among these, epoxy resins are preferred from the viewpoints of heat resistance and strength. Furthermore, the film for forming a semiconductor protection film of the present invention is such that a film having a high elastic modulus is preferred in view of enhancing protective properties. Therefore, a large amount of filler is included in the film. For this reason, the film may lack tackiness, or the film resin composition may become brittle. In order to prevent this, it is preferable to use a liquid epoxy resin.

The weight average molecular weight of the (A) thermosetting component is preferably equal to or greater than 100 and equal to or less than 49,000, and particularly preferably equal to or greater than 200 and equal to or less than 40,000. When the weight average molecular weight of the (A) thermosetting component is in the range described above, a balance can be achieved between high reactivity at the time of thermosetting and high protective properties for a member to be protected. Meanwhile, the weight average molecular weight in the present invention is a value measured by GPC (gel permeation chromatography) and calculated relative to polystyrene standards.

The content of the (A) thermosetting component is preferably equal to or more than 3% by mass and equal to or less than 35% by mass, and particularly preferably equal to or more than 5% by mass and equal to or less than 20% by mass, relative to the total amount of the resin composition that constitutes the film for forming a semiconductor protection film. When the content of the (A) thermosetting component is in the range described above, a balance can be achieved between high elastic modulus and toughness of the film for forming a semiconductor protection film after curing. Meanwhile, when the resin composition that constitutes the film for forming a semiconductor protection film of the present invention is prepared in a varnish form in which constituent components are dissolved or dispersed in a solvent, the content of the (A) thermosetting component is the percentage relative to the fraction excluding the solvent, that is, the total amount of the (A) thermosetting component, the (B) inorganic filler, and other additives.

In the case of using an epoxy resin as the (A) thermosetting component, it is preferable that the resin composition contains a curing agent. Examples of the curing agent include amine-based curing agents such as aliphatic polyamines including diethylenetriamine (DETA), triethylenetetramine (TETA), and meta-xylylenediamine (MXDA); aromatic polyamines including diaminodiphenylmethane (DDM), m-phenylenediamine (MPDA), and diaminodiphenylsulfone (DDS); and polyamine compounds including dicyandiamide (DICY), organic acid dihydrazides, and the like; acid anhydride-based curing agents such as alicyclic acid anhydrides (liquid acid anhydrides) including hexahydrophthalic anhydride (HHPA) and methyltetrahydrophthalic anhydride (MTHPA), and aromatic acid anhydrides including trimellitic anhydride (TMA), pyromelltic anhydride (PMDA), and benzophenonetetracarboxylic acid (BTDA); and phenolic curing agents such as phenolic resins. Among these, phenolic curing agents are preferred, and specific examples include various isomers of bisphenols such as bis(4-hydroxy-3,5-dimethylphenyl)methane (commonly known as tetramethylbisphenol F), 4,4′-sulfonyldiphenol, 4,4′-isopropylidenediphenol (commonly known as bisphenol A), bis(4-hydroxyphenyl)methane, bis(2-hydroxyphenyl)methane, (2-hydroxyphenyl)(4-hydroxyphenyl)methane, and among these, a mixture of three compounds such as bis(4-hydroxyphenyl)methane, bis(2-hydroxyphenyl)methane, and (2-hydroxyphenyl)(4-hydroxyphenyl)methane (for example, bisphenol F-D, manufactured by Honshu Chemical Industry Co., Ltd.); dihydroxybenzenes such as 1,2-benzenediol, 1,3-benzenediol, and 1,4-benzenediol; trihydroxybenzenes such as 1,2,4-benzenetriol; and dihydroxynaphthalenes such as 1,6-dihydroxynaphthalene; as well as various isomers of biphenols such as 2,2′-biphenol, and 4,4′-biphenol.

The content of the curing agent (particularly, a phenolic curing agent) is not particularly limited, but the content is preferably equal to or more than 1% by mass and equal to or less than 20% by mass, and particularly preferably equal to or more than 2% by mass and equal to or less than 10% by mass, relative to the total amount of the film resin composition. If the content is less than the lower limit, the effect of enhancing heat resistance may be decreased. If the content is greater than the upper limit, storage stability may deteriorate.

Furthermore, when the (A) thermosetting component is an epoxy resin, the equivalent ratio of the curing agent with respect to the epoxy equivalent can be calculated and determined, and it is preferable that the ratio of the equivalent of the functional group of the curing agent (for example, in the case of a phenolic resin, the hydroxyl group equivalent) with respect to the epoxy equivalent of the epoxy resin be equal to or greater than 0.3 and equal to or less than 3.0, and particularly preferably equal to or greater than 0.4 and equal to or less than 2.5. If the content is less than the lower limit, storage stability may deteriorate, and if the content is greater than the upper limit, the effect of enhancing heat resistance may be decreased.

When an epoxy resin is used as the (A) thermosetting component, there are no particular limitations, but it is preferable that the resin composition contains a curing catalyst that is capable of further enhancing the curability of the film for forming a semiconductor protection film. Examples of the curing catalyst include imidazoles, amine-based catalysts such as 1,8-diazabicyclo(5,4,0)undecene; and phosphorus-based catalysts such as triphenylphosphine. Among these, imidazoles which can achieve a balance between fast curability and storage stability of the film for forming a semiconductor protection film are preferred.

There are no particular limitations on the imidazoles, but examples thereof include 1-benzyl-2-methylimidazole, 1-benzyl-2-phenylimidazole, 1-cyanoethyl-2-ethyl-4-methylimidazole, 2-phenyl-4-methylimidazole, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, an isocyanuric acid adduct of 2,4-diamino-6-[2′-methylimidazolyl-(1′)]-ethyl-s-triazine, an isocyanuric acid adduct of 2-phenylimidazole, 2-phenyl-4,5-dihydroxymethylimidazole, 2-phenyl-4-methyl-5-hydroxymethylimidazole, 2,4-diamino-6-vinyl-s-triazine, an isocyanuric acid adduct of 2,4-diamino-6-vinyl-s-triazine, 2,4-diamino-6-methacryloyloxyethyl-s-triazine, and an isocyanuric acid adduct of 2,4-diamino-6-methacryloyloxyethyl-s-triazine. These compounds may be used singly, or two or more kinds may be used in combination. Among these, 2-phenyl-4,5-dihydroxymethylimidazole or 2-phenyl-4-methyl-5-hydroxymethylimidazole, which can both achieve an excellent balance between fast curability and storage stability of the film for forming a semiconductor protection film, are preferred.

The content of the curing catalyst is not particularly limited, but the content is preferably equal to or more than 0.01 parts by mass and equal to or less than 30 parts by mass, and particularly preferably equal to or more than 0.3 parts by mass and equal to or less than 10 parts by mass, relative to 100 parts by mass of the epoxy resin. When the content is in the range described above, a balance can be achieved between fast curability and storage stability of the film for forming a semiconductor protection film.

The average particle size of the curing catalyst is not particularly limited, but the average particle size is preferably 10 μm or less, and particularly preferably equal to or greater than 1 μm and equal to or less than 5 μm. When the average particle size is in the range described above, fast curability of the film for forming a semiconductor protection film can be secured.

In the resin composition that constitutes the film for forming a semiconductor protection film of the present invention, (B) an inorganic filler can be used. There are no particular limitations on the (B) inorganic filler, and for example, alumina, silica, aluminum oxide, calcium carbonate, magnesium carbonate, and aluminum nitride can be used. These may be used singly, or two or more kinds may be used in combination. Among them, a particularly preferred inorganic filler is alumina. The elastic modulus of alumina is 4 to 5 times that of silica, and can thus increase the elastic modulus of the film for forming a semiconductor protection film after curing. In the (B) inorganic filler, the content of alumina is preferably adjusted to equal to or more than 50% by mass and equal to or less than 100% by mass. Furthermore, when silica and alumina are combined, the abrasion of the dicing blade at the time of dicing the film for forming a semiconductor protection film can be suppressed, while the elastic modulus of the film for forming a semiconductor protection film after curing is increased. In the case of using alumina and silica in combination, silica is preferably used in an amount of equal to or more than 0.1 times and equal to or less than 1.0 times with respect to alumina.

The particle size distributions of the (B) inorganic filler preferably respectively have at least one maximum peak in the range of equal to or greater than 1 nm to equal to or less than 1,000 nm and in the range of equal to or greater than 1,000 nm and equal to or less than 10,000 nm. These fillers can be easily obtained by mixing fillers having different particle size distributions; however, the filler can be thereby packed closest, and the content of the filler can be increased. The method for measuring the particle size distribution of the (B) inorganic filler is as follows. The measurement of the particle size distribution is carried out by dispersing the inorganic filler in water through ultrasonication for one minute using a laser diffraction type particle size distribution analyzer, SALD-7000 (manufactured by Shimadzu Corp.).

The content of the (B) inorganic filler is preferably equal to or more than 60% by mass and equal to or less than 95% by mass, and particularly preferably equal to or more than 80% by mass and equal to or less than 90% by mass, relative to the total amount of the resin composition that constitutes the film for forming a semiconductor protection film. When the content is in the range described above, a film for forming a semiconductor protection film having an excellent elastic modulus upon heating can be obtained.

In the resin composition that constitutes the film for forming a semiconductor protection film of the present invention, (C) a colorant can be used. There are no particular limitations on the (C) colorant, and for example, pigments or dyes such as carbon black, graphite, titanium carbon, titanium dioxide, lanthanum hexaboride (LaB₆), titanium black, and phthalocyanines can be used. These may be used singly, or two or more kinds may be used in combination. The content of the (C) colorant is preferably equal to or more than 0.1% by mass and equal to or less than 10% by mass, and particularly preferably equal to or more than 0.2% by mass and equal to or less than 5% by mass, relative to the total amount of the resin composition that constitutes the film for forming a semiconductor protection film of the present invention. If the amount of use of the colorant is less than the lower limit, coloration is not sufficiently achieved, and the visibility after laser marking tends to decrease. If the amount of use is greater than the upper limit, there is a possibility that the elastic modulus or heat resistance of the film for forming a semiconductor protection film may decrease.

Although not particularly limited, the resin composition that constitutes the film for forming semiconductor protection film of the present invention may further contain a coupling agent. Thereby, the adhesiveness between the film for forming a semiconductor protection film and the surface of the object to be adhered (semiconductor element) can be further enhanced. Examples of the coupling agent include silane-based coupling agents, titanium-based coupling agents, and aluminum-based coupling agents, but silane-based coupling agents that exhibit excellent heat resistance after the curing of the film for forming a semiconductor protection film are preferred.

There are no particular limitations, but examples of the silane-based coupling agents include vinyltrichlorosilane, vinyltrimethoxysilane, vinyltriethoxysilane, β-(3,4-epoxycyclohexyl)ethyltrimethoxysilane, γ-glycidoxypropyltrimethoxysilane, γ-glycidoxypropylmethyldimethoxysilane, γ-methacryloxypropyltrimethoxysilane, γ-methacryloxypropylmethyldiethoxysilane, γ-methacryloxypropyltriethoxysilane, N-β-(aminoethyl) γ-aminopropylmethyldimethoxysilane, N-β-(aminoethyl) γ-amniopropyltrimethoxysilane, N-β-(aminoethyl) γ-aminopropyltriethoxysilane, γ-aminopropyltrimethoxysilane, γ-aminopropyltriethoxysilane, N-phenyl-γ-aminopropyltrimethoxysilane, γ-chloropropyltrimethoxysilane, γ-mercaptopropyltrimethoxysilane, 3-isocyanatopropyltriethoxysilane, and 3-acryloxypropyltrimethoxysilane. These may be used singly, or two or more kinds may be used in combination.

The content of the coupling agent is not particularly limited, but the content is preferably equal to or more than 0.01 parts by mass and equal to or less than 10 parts by mass, and particularly equal to or more than 0.5 parts by mass to equal to or less than 10 parts by mass, relative to 100 parts by mass of the (A) thermosetting component. When the content is in the range described above, an effect of acquiring excellent adhesiveness between the objects to be adhered (a semiconductor element, and a substrate on which the semiconductor element is mounted) can be obtained.

The resin composition that constitutes the film for forming a semiconductor protection film of the present invention can contain additives such as a plastic resin, a leveling agent, a defoamant, and an organic peroxide, to the extent that the purpose of the present invention is not impaired.

The resin composition that constitutes the film for forming a semiconductor protection film of the present invention can be prepared into a varnish by dissolving or dispersing the various components such as the component (A), component (B), component (C), and other additives in an organic solvent, for example, a solvent such as methyl ethyl ketone, acetone, toluene, or dimethylformaldehyde. When this varnish-like film resin composition is formed into a layer form, the solvent is removed, and the film resin composition is dried, the film resin composition can be formed into a film form.

Although not particularly limited, the film for forming a semiconductor protection film of the present invention is such that when the film resin composition prepared in a varnish form is formed into a layer by applying the film resin composition on the surface of a base material film, subsequently the solvent is removed, and the film resin composition is dried, a film-like film for forming a semiconductor protection film can be formed on the base material film, and this can be used as a base material film-attached film for forming a semiconductor protection film.

The base material film is a film supporting base material which is excellent in the film properties capable of maintaining the film shape of the film for forming a semiconductor protection film, for example, fracture strength and flexibility. This base material film preferably has optical transparency. Examples of such a base material film include films of polyethylene terephthalate (PET), polypropylene (PP), and polyethylene (PE). Polyethylene terephthalate (PET) is preferred from the viewpoints of having an excellent balance between optical transparency and fracture strength.

Furthermore, the film for forming a semiconductor protection film of the present invention may be provided on the surface with a cover film for protecting the film for forming a semiconductor protection film. As this cover film, use can be made of any material having film properties capable of maintaining the film shape of the film for forming a semiconductor protection film, for example, any material that is excellent in fracture strength, flexibility and the like and has satisfactory peelability from the film for forming a semiconductor protection film in particular. Examples thereof include polyethylene terephthalate (PET), polypropylene (PP), and polyethylene (PE). Meanwhile, the cover film may be formed from an opaque material.

Although not particularly limited, more specifically, the film for forming a semiconductor protection film can be obtained by applying a varnish of the resin composition that constitutes the film for forming a semiconductor protection film on a base material film using a comma coater, a die coater, a gravure coater or the like, and drying the resin composition to remove the solvent. The thickness of the film for forming a semiconductor protection film is not particularly limited, but the thickness is preferably equal to or greater than 3 μm to equal to or less than 100 μm, and particularly preferably equal to or greater than 5 μm and equal to or less than 60 μm. When the thickness is in the range described above, the thickness accuracy of the film for forming a semiconductor protection film can be easily controlled.

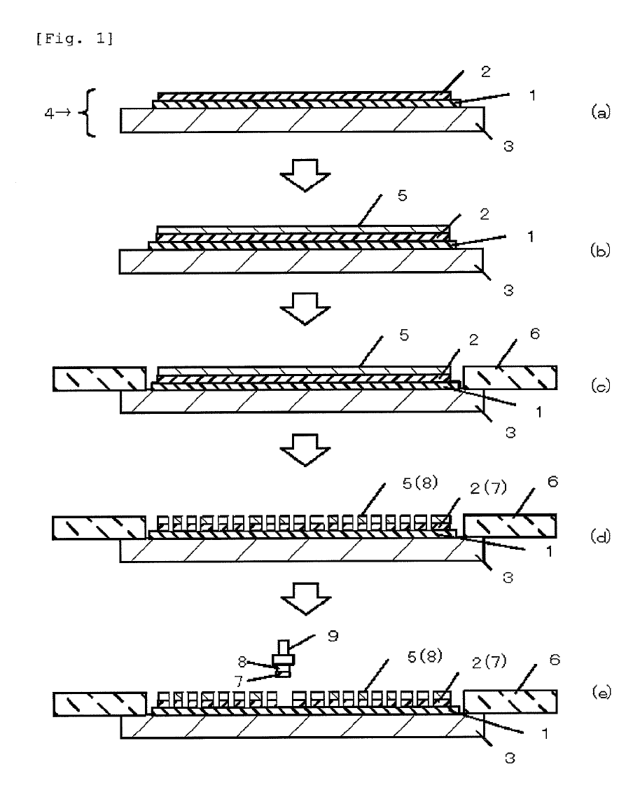

Next, a method for producing a semiconductor device will be described based on FIG. 1, but the method for producing the semiconductor device according to the present invention is not intended to be limited to this. For example, the method may include a step of cutting the film for forming a semiconductor protection film described above to a size that is approximately the same as the size of the semiconductor element, and then directly bonding the film to the semiconductor element. FIG. 1 is a flow diagram for the production of a semiconductor device. As illustrated in FIG. 1, a dicing sheet-attached film for forming a semiconductor protection film 4 obtained by laminating a dicing sheet 3, a base material film 1, and a film for forming a semiconductor protection film 2, is placed on a dicer table that is not shown in the drawing (FIG. 1(a)). At the center of the laminate, a semiconductor wafer 5 is placed such that the surface where the circuit of a semiconductor element is not formed faces the film for forming a semiconductor protection film 2, and the assembly is lightly pressed to laminate the semiconductor wafer 5 (FIG. 1(b)).

Next, a wafer ring 6 is placed around the semiconductor wafer 5, and the outer periphery of the dicing sheet 3 is fixed with the wafer ring 6 (FIG. 1(c)). The film for forming a semiconductor protection film 2 and the semiconductor wafer 5 are cut together with a blade that is not shown in the drawing, and the semiconductor wafer 5 is divided into individual pieces (FIG. 1(d)). At this time, the dicing sheet-attached film for forming a semiconductor protection film 4 has a buffering effect, and thus prevents cracking, chipping and the like when the semiconductor wafer 5 is cut. Meanwhile, it is also acceptable to attach the semiconductor wafer 5 in advance to the film for forming a semiconductor protection film 4, and then place the assembly on the dicer table.

Next, the film for forming a semiconductor protection film 2 is stretched with an expanding apparatus that is not depicted, and the individually divided semiconductor wafers 5 (semiconductor elements 8) are spread at a constant interval. Subsequently, the semiconductor elements are mounted on a substrate using a flip chip bonder. First, the chips are picked up with a collet 9 (FIG. 1(e)), and then the chips are reversed, and are mounted on a substrate that is not depicted, in a face-down manner.

Here, in regard to the film for semiconductor protection film 2 (semiconductor protection film 7), since the adhesive force of the film to the base material film 1 is adjusted, when the semiconductor elements 8 are picked up, peeling occurs between the film for forming a semiconductor protection film 2 (semiconductor protection film 7) and the base material film 1, and the individually divided semiconductors 8 have the semiconductor protection film 7 attached thereto.

The substrate on which the semiconductor elements 8 are mounted is heated in an oven or the like at a temperature equal to or higher than the temperature at which the bumps that electrically bond the electrode pad of the semiconductor elements 8 and the electrode pad of the substrate, melt (for example, equal to or higher than 200° C. and equal to or lower than 280° C.), and thereby bonding of the semiconductor elements and the substrate is completed. Thereafter, a liquid epoxy resin, which is called an underfill material, is poured in between the semiconductor elements and the substrate, and is cured. Meanwhile, laser engraving may be carried out after the underfill material and the semiconductor protection film 7 are thermally cured.

The semiconductor protection film 7 is thermally cured simultaneously with the curing of the underfill material, and thereby a semiconductor device in which the semiconductor protection film 7 is formed on the semiconductor element 8 is obtained.

The elastic modulus at 25° C. after curing of the film for forming a semiconductor protection film is preferably equal to or greater than 10 GPa and equal to or less than 40 GPa. Thereby, warpage of the semiconductor device in which the semiconductor protection film 7 is formed on the semiconductor element 8 can be reduced. The elastic modulus at 25° C. can be determined such that, for example, the dynamic viscoelasticity of the semiconductor protection film 7 (film for forming a semiconductor protection film 2) after curing is measured using a dynamic viscoelastometer manufactured by Seiko Instruments, Inc., in a tensile mode under the conditions of a rate of temperature increase of 3° C./min and a frequency of 10 Hz, and thus the storage elastic modulus at 25° C. can be determined.

As such, the method for producing a face-down type semiconductor device has been described based on FIG. 1, but the method for producing a semiconductor device of the present invention is not intended to be limited to this. For example, the method can also be applied to the production of a semiconductor device having a TSV (Through-Silicon Via) type structure in which a semiconductor element having a through hole via and having an electrode formed on the surface on the reverse side of the circuit surface, is laminated in plural layers in a face-up manner.

### EXAMPLES

Hereinafter, the present invention will be described in detail by way of Examples and Comparative Examples, but the present invention is not intended to be limited to this.

### Example 1

### 1. Preparation of Film Resin Composition Varnish

100 parts by mass of LX-SB10 (diglycidylamine type epoxy resin) (epoxy equivalent 110 g/eq, weight average molecular weight 291, manufactured by Daiso Co., Ltd., liquid at normal temperature) and 15 parts by mass of a modified phenoxy resin of YX6954B35 (concentration of modified phenoxy resin in methyl ethyl ketone: 35% by mass) (epoxy equivalent 12,000 g/eq, weight average molecular weight 39,000, manufactured by Japan Epoxy Resin Co., Ltd.) as the (A) thermosetting components; 228 parts by mass of alumina of AC2050-MNA (concentration of spherical alumina in methyl ethyl ketone: 70% by mass) (manufactured by Admatechs Co., Ltd., average particle size: 0.7 μm, maximum peak: 860 nm) and 228 parts by mass of silica of SE2050-LE (concentration of spherical silica in methyl ethyl ketone: 75% by mass) (manufactured by Admatechs Co., Ltd., average particle size: 0.5 μm, maximum peak: 580 nm) as the (B) inorganic fillers; 15 parts by mass of carbon black of MT-190BK (concentration of carbon black in toluene/3-methoxybutyl acetate: 15% by mass) (manufactured by Tokushiki Co., Ltd.) as the (C) colorant; 38 parts by mass of MEH-7500 (phenolic resin) (hydroxyl group equivalent: 97 g/OH group, manufactured by Meiwa Plastic Industries, Ltd.) as a curing agent; 3.0 parts by mass of γ-glycidoxypropyltrimethoxysilane (KBM403E, manufactured by Shin-Etsu Chemical Co., Ltd.) as a coupling agent; 0.4 parts by mass of an imidazole compound (2PHZ-PW, average particle size: 3.2 μm, manufactured by Shikoku Chemicals Corp.) as a curing catalyst; and 7.3 parts by mass of BYK-361N (manufactured by BYK-Chemie Japan K.K.) as a leveling agent were dissolved in methyl ethyl ketone (MEK), and thus a film resin composition varnish having a resin solids content of 90% was obtained.

### 2. Production of Film for Forming Semiconductor Protection Film

Thereafter, the film resin composition varnish was applied on a base material film (thickness: 38 μm) made of PET, and was dried for 15 minutes at 80° C. Thus, a film for forming a semiconductor protection film having a thickness of 60 μm was formed. Meanwhile, for a film for forming a semiconductor protection film obtained after curing the film for forming a semiconductor protection film thus obtained under the conditions of 180° C. for 2 hours, the storage modulus at 25° C. measured using a dynamic viscoelastometer manufactured by Seiko Instruments, Inc. in a tensile mode under the conditions of a rate of temperature increase of 3° C./min and a frequency of 10 Hz, was 12.0 GPa.

### 3. Production of Dicing Sheet-Attached Film for Forming Semiconductor Protection Film

A cover film made of PET for the film for forming a semiconductor protection film was laminated. Subsequently, the base material film and the film layer for forming a semiconductor protection film were half-cut, and only the areas to be bonded to the wafer were left, while removing the peripheral areas. Thereafter, a dicing sheet (a polyethylene film laminated with a tacky adhesive layer composed of 100 parts by mass of a copolymer obtained by copolymerizing 70% by mass of butyl acrylate and 30% by mass of 2-ethylhexyl acrylate and having a weight average molecular weight of 500,000, and 3 parts by mass of tolylene diisocyanate (Coronate T-100, manufactured by Nippon Polyurethane Industry Co., Ltd.)) was laminated to be bonded to the base material film. Thereby, a dicing sheet-attached film for forming a semiconductor protection film composed of a dicing sheet, a base material film, a film for the semiconductor protection film, and a cover film in this order, was obtained.

### 4. Production of Semiconductor Device

A semiconductor device was produced by the following procedure.

The film for forming a semiconductor protection film from which the cover film was peeled off, and the back surface of an 8-inch semiconductor wafer having a thickness of 100 μm were disposed to face each other and bonded at a temperature of 60° C. Thus, a semiconductor wafer pasted with the dicing sheet-attached film for forming a semiconductor protection film was obtained.

Thereafter, this semiconductor wafer pasted with the dicing sheet-attached film for forming a semiconductor protection film was diced (cut) to the size of a semiconductor element which measured 10 mm×10 mm, using a dicing saw under the conditions of a speed of spindle rotation of 30,000 rpm, and a cutting rate of 50 mm/sec. Subsequently, the dicing sheet-attached film for forming a semiconductor protection film was lifted up from the back surface to cause detachment between the base material film and the film for forming a semiconductor protection film. Thus, a semiconductor protection film-attached semiconductor element was obtained.

This semiconductor protection film-attached semiconductor element (10 mm×10 mm, 100 μm thick, level difference of circuit at the element surface: 1 to 5 μm) was mounted on a bismaleimide-triazine resin wiring substrate (14 mm×14 mm, 135 μm thick, level difference of circuit at the element surface: 5 to 10 μm) coated with a solder resist (manufactured by Taiyo Ink Manufacturing Co., Ltd., trade name: AUS308) in a face-down manner. The semiconductor element and the wiring substrate were compressed, with solder bumps disposed therebetween, under the conditions of 130° C., 5 N and 1.0 second, and thus the semiconductor element and the bismaleimide-triazine wiring substrate were provisionally adhered. The bismaleimide-triazine wiring substrate to which the semiconductor element was provisionally adhered was subjected to a heat treatment under the conditions of 250° C. for 10 seconds. Thereafter, an underfill material was poured between the semiconductor element and the board, and the underfill material was cured at 150° C. for 2 hours. Thus, a semiconductor device (flip chip package) was obtained.

### Example 2

A semiconductor device (flip chip package) was obtained in the same manner as in Example 1, except that the composition of the film resin composition varnish was changed as described below.

The (B) inorganic filler was changed to 244 parts by mass of DAW-05 (spherical alumina) (manufactured by Denki Kagaku Kogyo K.K., average particle size: 5 μm, maximum peak: 2,800 nm).

Meanwhile, the storage modulus at 25° C. of the film for forming a semiconductor protection film thus obtained after curing under the conditions of 180° C. for 2 hours was 10.1 GPa.

### Example 3

A semiconductor device (flip chip package) was obtained in the same manner as in Example 1, except that the composition of the film resin composition varnish was changed as described below.

The (B) inorganic filler was changed to 257 parts by mass of alumina of AC2050-MNA (concentration of spherical alumina in methyl ethyl ketone: 70% by mass) (manufactured by Admatechs Co., Ltd., average particle size: 0.7 μm, maximum peak: 860 nm) and 900 parts by mass of DAW-05 (spherical alumina) (manufactured by Denki Kagaku Kogyo K.K., average particle size: 5 μm, maximum peak: 2,800 nm).

Meanwhile, the storage modulus at 25° C. of the film for forming a semiconductor protection film thus obtained after curing was 28.3 GPa.

### Comparative Example 1

A semiconductor device (flip chip package) was obtained in the same manner as in Example 1, except that the composition of the film resin composition varnish was changed as described below.

100 parts by mass of LX-SB10 (diglycidylamine type epoxy resin) (epoxy equivalent 110 g/eq, weight average molecular weight 291, manufactured by Daiso Co., Ltd., liquid at normal temperature) and 15 parts by mass of a modified phenoxy resin of YX6954B35 (concentration of modified phenoxy resin in methyl ethyl ketone 35% by mass) (epoxy equivalent: 12,000 g/eq, weight average molecular weight 39,000, manufactured by Japan Epoxy Resin Co., Ltd.) as the (A) thermosetting components; 38 parts by mass of MEH-7500 (phenolic resin) (hydroxyl group equivalent: 97 g/OH group, manufactured by Meiwa Plastic Industry Co., Ltd.) as a curing agent; 3.0 parts by mass of γ-glycidoxypropyltrimethoxysilane (KBM403E, manufactured by Shin-Etsu Chemical Co., Ltd.) as a coupling agent; 0.4 parts by mass of an imidazole compound (2PHZ-PW, average particle size: 3.2 μm, manufactured by Shikoku Chemicals Corp.) as a curing catalyst; and 7.3 parts by mass of BYK-361N (manufactured by BYK-Chemie Japan K.K.) as a leveling agent were dissolved in methyl ethyl ketone (MEK), and thus a film resin composition varnish having a resin solids content of 90% was obtained.

Meanwhile, the storage modulus at 25° C. of the film for forming a semiconductor protection film after curing was 3.1 GPa.

Evaluation Items and Evaluation Results

Evaluation of collet marks: The dicing sheet-attached film for forming a semiconductor protection film was lifted up from the back surface to cause detachment between the dicing sheet and the film for forming a semiconductor protection film. Thus, the presence or absence of collet marks when the semiconductor protection film-attached semiconductor element was mounted on the substrate using a flip chip bonder, was evaluated by visual inspection. No collet marks were observed in the semiconductor protection films of Example 1, Example 2 and Example 3, which had large contents of the inorganic fillers, but in the semiconductor protection film of Comparative Example 1, which had a low content of the inorganic filler, collet marks were observed. When collet marks are imprinted in the semiconductor protection film, the product quality as a semiconductor device is deteriorated.

Evaluation of warpage in semiconductor device: For the obtained semiconductor devices (flip chip packages), the displacement in the height direction was measured using a temperature variable laser three-dimensional displacement measurement apparatus (LS150-RT50/5) manufactured by Hitachi Tsuchiura Engineering Co., Ltd. The largest value of the displacement difference was defined as the amount of warpage of the semiconductor device. A semiconductor device having an amount of warpage of 100 μm or less was rated as o, and a semiconductor device having an amount of warpage of larger than 100 μm was rated as x. The results are presented in Table 1.

TABLE 1

| | | | Example 1 | Example 2 | Example 3 | Comp. Ex. 1 |
|---|---|---|---|---|---|---|
| Film resin | (A) Thermosetting | LX-SB10 | 100 | 100 | 100 | 100 |
| composition | component | Modified phenoxy resin of | 15 | 15 | 15 | 15 |
| | | YX6954B35 | | | | |
| | (B) Inorganic filler | Alumina of AC2050-MNA | 228 | | 257 | |
| | | Silica of SE2050-LE | 228 | | | |
| | | DAW-05 | | 244 | 900 | |
| | (C) Colorant | MT-190BK | 15 | 15 | 15 | |
| | Curing agent | MEH-7500 | 38 | 38 | 38 | 38 |
| | Silane coupling agent | KBM403E | 3.0 | 3.0 | 3.0 | 3.0 |
| | Curing catalyst | 2PHZ-PW | 0.4 | 0.4 | 0.4 | 0.4 |
| | Leveling agent | BYK-361N | 7.3 | 7.3 | 7.3 | 7.3 |

| | | | | | |
|---|---|---|---|---|---|
| Evaluation | Storage modulus at 25° C. of film for forming | 12.0 | 10.1 | 28.3 | 3.1 |
| results | semiconductor protection film after curing [GPa] | | | | |
| | Warpage of semiconductor device | ◯ | ◯ | ◯ | X |

According to the present invention, a film for forming a semiconductor protection film having excellent protective properties for semiconductor elements, and a semiconductor device having a semiconductor protection film with less warpage, which is formed by using the film for forming a semiconductor protection film, can be obtained. Therefore, the present invention is suitable for the use in face-down type semiconductor devices such as μBGA or CSP, having a configuration in which the semiconductor element is exposed, or in TSV type semiconductor devices in which a semiconductor element having a through hole via and having an electrode formed on the surface on the reverse side of the circuit surface, is laminated in plural layers in a face-up manner.

As such, the embodiments of the present invention have been described, but these are only examples of the present invention, and various constitutions other than those described above can also be employed.

For example, the following embodiments may be taken as examples.

[1] A dicing sheet-attached film for forming a semiconductor protection film, including a dicing sheet and the above-described film for forming a semiconductor protection film laminated on one surface of the dicing sheet.
[2] The dicing sheet-attached film for forming a semiconductor protection film as described in the [1], wherein the dicing sheet and the film for forming a semiconductor protection film are laminated, with a base material film interposed therebetween.
[3] A method for producing a semiconductor device in which a surface of a semiconductor element that is mounted on a structure such as a substrate and is located on the outermost side, the surface being on the reverse side of the surface at which the semiconductor element is mounted on the structure, is protected by a semiconductor protection film,

the method including the steps of:

laminating a dicing sheet to the above-described film for forming a semiconductor protection film;

laminating a semiconductor wafer such that the semiconductor element surface on the reverse side of the surface at which the semiconductor element is mounted on the structure, is in contact with the surface on the reverse side of the dicing sheet-laminated surface of the film for forming a semiconductor protection film;

dicing the semiconductor wafer together with the film for forming a semiconductor protection film to a predetermined size; and

causing detachment between the dicing sheet and the film for forming a semiconductor protection film, and obtaining a semiconductor protection film-attached semiconductor element.

[4] A semiconductor device in which a surface of a semiconductor element that is mounted on a structure such as a substrate and is located on the outermost side, the surface being on the reverse side of the surface at which the semiconductor element is mounted on the structure, is protected by a semiconductor protection film,

the semiconductor device being produced by the method for producing a semiconductor device of the [3].

1. A film for forming a semiconductor protection film, which protects a surface of a semiconductor element that is mounted on a base material and is located on the outermost side, the surface being on the reverse side of the surface at which the semiconductor element is mounted on the base material,
wherein a resin composition that constitutes the film for forming a semiconductor protection film comprises (A) a thermosetting component and (B) an inorganic filler.

2. The film for forming a semiconductor protection film according to claim 1, wherein the weight average molecular weight of the resin component in the resin composition is equal to or greater than 100 and equal to or less than 49,000.

3. The film for forming a semiconductor protection film according to claim 1, wherein the content of the (B) inorganic filler in the resin composition is equal to or more than 60% by mass and equal to or less than 95% by mass.

4. The film for forming a semiconductor protection film according to claim 1, wherein the resin composition further comprises (C) a colorant.

5. The film for forming a semiconductor protection film according to claim 1, wherein an elastic modulus at 25° C. of the film for forming a semiconductor protection film after curing, which is measured using a dynamic viscoelastometer at a frequency of 10 Hz, is equal to or greater than 10 GPa and equal to or less than 40 GPa.

6. The film for forming a semiconductor protection film according to claim 1, wherein the (B) inorganic filler comprises two kinds of inorganic fillers having different particle size distributions, and the particle size distributions of the (B) inorganic fillers respectively have at least one maximum peak in the range of equal to or greater than 1 nm and equal to or less than 1,000 nm, and in the range of equal to or greater than 1,000 nm and equal to or less than 10,000 nm.

7. The film for forming a semiconductor protection film according to claim 1, wherein the (B) inorganic filler comprises alumina.

8. The film for forming a semiconductor protection film according to claim 7, wherein the (B) inorganic filler further comprises silica.

9. The film for forming a semiconductor protection film according to claim 1, wherein the (A) thermosetting component comprises an epoxy resin.

10. The film for forming a semiconductor protection film according to claim 1, wherein the (A) thermosetting component comprises a liquid epoxy resin.

11. The film for forming a semiconductor protection film according to claim 1, wherein the (A) thermosetting component comprises a liquid epoxy resin, and the (B) inorganic filler comprises alumina.

12. The film for forming a semiconductor protection film according to claim 9, wherein the (A) thermosetting component further comprises a phenoxy resin.

13. The film for forming a semiconductor protection film according to claim 1, wherein the film for forming a semiconductor protection film is used to protect a surface on the reverse side of the circuit surface of a semiconductor element in a face-down type semiconductor device in which the circuit surface of the semiconductor element is disposed toward the semiconductor wiring substrate side.

14. The film for forming a semiconductor protection film according to claim 1, wherein the film for forming a semiconductor protection film is used to protect a circuit surface of a semiconductor element that is located on the outermost side, in a TSV (Through-Silicon Via) type semiconductor device in which a semiconductor element having a through hole via and having an electrode formed on the surface on the reverse side of the circuit surface, is laminated in plural layers in a face-up manner.

15. A semiconductor device in which a surface of a semiconductor element that is mounted on a base material and is located on the outermost side, the surface being on the reverse side of the surface at which the semiconductor element is mounted on the base material, is protected by a semiconductor protection film,
wherein the semiconductor protection film is formed from a cured product of the film for forming a semiconductor protection film according to claim 1.

16. The semiconductor device according to claim 15, wherein the semiconductor device has a face-down type structure in which the circuit surface of the semiconductor element is disposed toward the semiconductor wiring substrate side.

17. The semiconductor device according to claim 15, wherein the semiconductor device has a TSV (Through-Silicon Via) type structure in which a semiconductor element having a through hole via and having an electrode formed on the surface on the reverse side of the circuit surface, is laminated in plural layers in a face-up manner.
